(19) United States
(12) Patent Application Publication
(10) Pub. No.: US 2021/0144324 A1
(43) Pub. Date: May 13, 2021

(54) COMPLEMENTARY METAL-OXIDE-SEMICONDUCTOR IMAGE SENSORS WITH SUBMICRON PIXELS AND PUNCH THROUGH CHARGE TRANSFER

(71) Applicant: SEMICONDUCTOR COMPONENTS INDUSTRIES, LLC, Phoenix, AZ (US)

(72) Inventor: Jaroslav HYNECEK, Allen, TX (US)

(73) Assignee: SEMICONDUCTOR COMPONENTS INDUSTRIES, LLC, Phoenix, AZ (US)

(21) Appl. No.: 16/679,398

(22) Filed: Nov. 11, 2019

(51) Int. Cl. H04N 5/374; H01L 27/146

(52) U.S. Cl. CPC H04N 5/374; H01L 27/14634; H01L 27/14612; H01L 27/14636; H04N 5/379; H01L 27/1463; H01L 27/1464; H01L 27/14603; H01L 27/14643

(57) ABSTRACT

A backside illuminated (BSI) complementary metal-oxide-semiconductor (CMOS) image sensor array may operate in a rolling shutter scanning mode. The CMOS image sensor may use chip stacking technology with chip-to-chip electrical connections between the top image sensing chip and carrier chip pixel circuits. Each chip-to-chip connection may electrically connect groups of pixels at floating diffusion nodes to a readout circuit. This arrangement allows for small, submicron sized pixels to be formed while using bonding pads that have a larger size. The top light sensing chip pixels do not have transfer gates for lateral charge transfer from photodiodes to the floating diffusion regions. The charge transfer from the photodiode regions is accomplished using a charge punch through technique in a vertical direction. This type of arrangement allows for submicron size pixels in a very large sensor array.

### BACKGROUND

The disclosed invention relates to solid-state image sensor arrays, specifically to complementary metal-oxide-semiconductor (CMOS) image sensor arrays that are illuminated from the back side of the substrate and operate in the Rolling Shutter (RS) scanning mode.

Modern electronic devices such as cellular telephones, cameras, and computers often use digital image sensors. Image sensors (sometimes referred to as imagers) may be formed from a two-dimensional array of image sensing pixels. Each pixel includes a photosensitive element that receives incident photons (light) and converts the photons into electrical signals. Image sensors are sometimes designed to provide images to electronic devices using a Joint Photographic Experts Group (JPEG) format.

Reducing the size of imaging pixels in an image sensor may be desirable to increase image sensor resolution. However, in very small imaging pixels (e.g., submicron size pixels) it is difficult to include in the pixels conventional pixel circuits such as the charge transfer gate, the Source Follower (SF) transistor, the addressing transistor, and the reset transistor.

It would therefore be desirable to be able to provide improved arrangements for imaging pixels in image sensors.

### BRIEF DESCRIPTION OF THE DRAWINGS

FIG. 1 is a schematic diagram of an illustrative electronic device with an image sensor in accordance with an embodiment.

FIG. 2 is a perspective view of an illustrative image sensor with multiple chips and electrically conductive bonds between the upper chip and middle chip in accordance with an embodiment.

FIG. 3 is a cross-sectional side view of illustrative pixels sharing the same hybrid bond pad in accordance with an embodiment.

FIG. 4 is a top view of an image sensor showing illustrative hybrid bond pad placement on top of the pixel array including connections of several pixel's floating diffusions to a single bus line and to a hybrid bonding pad in accordance with an embodiment.

FIG. 5 is a circuit diagram of two adjacent (in a column direction) pixel circuits and their connection to various biasing lines and to a column sense line using a source follower with a row addressing transistor in accordance with an embodiment.

FIG. 6 is a timing diagram for the circuit of FIG. 5 in accordance with an embodiment.

### DETAILED DESCRIPTION

The following relates to solid-state image sensor arrays that may be included in electronic devices. Specifically, electronic devices may include complementary metal-oxide-semiconductor (CMOS) image sensor arrays with small (e.g., submicron) imaging pixels that are illuminated from the back side of the substrate and operate in the Rolling Shutter (RS) scanning mode. An image sensor may include stacked chips to improve image sensor performance.

To form small imaging pixels such as submicron imaging pixels (e.g., imaging pixels with a length and width less than 1 micron), the image sensor may include multiple chips that are stacked. Employing a stacked chip image sensor allows most of the pixel circuits from the image sensing chip (e.g., the charge transfer gate, the source follower transistor, the addressing transistor, and/or the reset transistor) to move onto the carrier chip. This makes the image sensing photodiode, located on a back-side illuminated (BSI) top chip, very efficient in converting photons to electrons. Therefore, the image sensing photodiodes of this type have high quantum efficiency (QE) and high charge storing capacity even with the small submicron size. Some stacked chips may be electrically connected using chip-to-chip bonding pads. However, these types of bonding pads may have a larger than desired size (e.g., larger than submicron size) and also may require predetermined distance margins between them to allow for manufacturing tolerances.

Therefore, the pixel charge transferring to Floating Diffusion (FD) may be implemented in a vertical direction without a MOS charge transferring gate using a charge punch through mechanism. In this type of arrangement, the chip-to-chip bonding pad size does not liming the image sensor pixel size and submicron pixels having a high efficiency may be formed.

An electronic device with a digital camera module and an image sensor is shown in FIG. 1. Electronic device 10 may be a digital camera, a computer, a cellular telephone, a medical device, or other electronic device. Camera module 12 (sometimes referred to as an imaging device) may include image sensor 14 and one or more lenses 28. During operation, lenses 28 (sometimes referred to as optics 28) focus light onto image sensor 14. Image sensor 14 includes photosensitive elements (e.g., pixels) that convert the light into analog signals that are later converted to digital data. Image sensors may have any number of pixels (e.g., hundreds, thousands, millions, or more). A typical image sensor may, for example, have millions of pixels (e.g., megapixels). As examples, image sensor 14 may include bias circuitry signal buffering circuits (e.g., source follower and load circuits), sample and hold circuitry, correlated double sampling (CDS) circuitry, amplifier circuitry, analog-to-digital (ADC) converter circuitry, data output circuitry, memory (e.g., data buffering circuitry), address circuitry, etc.

Still and video image data from image sensor 14 may be provided to image processing and data formatting circuitry 16 via path 26. Image processing and data formatting circuitry 16 may be used to perform image processing functions such as automatic focusing functions, depth sensing, data formatting, adjusting white balance and exposure, implementing video image stabilization, face detection, etc.

Image processing and data formatting circuitry 16 may also be used to compress raw camera image files if desired (e.g., to Joint Photographic Experts Group or JPEG format). In a typical arrangement, which is sometimes referred to as a system on chip (SOC) arrangement, camera sensor 14 and image processing and data formatting circuitry 16 are implemented on a common integrated circuit chip. The use of a single integrated circuit chip to implement camera sensor 14 and image processing and data formatting circuitry 16 can help to reduce costs. This is, however, merely illustrative. If desired, camera sensor 14 and image processing and data formatting circuitry 16 may be implemented using separate integrated circuit chips.

Camera module 12 may convey acquired image data to host subsystems 20 over path 18 (e.g., image processing and data formatting circuitry 16 may convey image data to subsystems 20). Electronic device 10 typically provides a user with numerous high-level functions. In a computer or advanced cellular telephone, for example, a user may be provided with the ability to run user applications. To implement these functions, host subsystem 20 of electronic device 10 may include storage and processing circuitry 24 and input-output devices 22 such as keypads, input-output ports, joysticks, and displays. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, or other processing circuits.

An illustrative image sensor such as image sensor 14 in FIG. 1 is shown in FIG. 2. Image sensor 14 may sense light by converting impinging photons into electrons or holes that are integrated (collected) in sensor pixels. After completion of an integration cycle, collected charge may be converted into a voltage, which may be supplied to the output terminals of the sensor. In CMOS image sensors, the charge to voltage conversions are accomplished directly in the pixels themselves and the analog pixel voltage is transferred to the output terminals through various pixel addressing and scanning schemes. The analog signal may also be converted on-chip to a digital equivalent before reaching the chip output. The pixels may include a buffer amplifier such as a Source Follower (SF) which drives the sense lines that are connected to pixels by suitable addressing transistors. After charge to voltage conversion is completed and the resulting signal is transferred out from the pixels, the pixels may be reset in order to be ready to accumulate new charge. Some pixels may use a Floating Diffusion (FD) as a charge detection node. In these pixels, the reset may be accomplished by turning on a reset transistor that conductively connects the FD node to a voltage reference. In some embodiments, the voltage reference for the FD node may also be the pixel SF drain node. This step removes collected charge from the floating diffusion. However, it also generates kTC reset noise. This kTC reset noise may be removed from the signal using correlated double sampling (CDS) signal processing in order to reduce noise in the sensor. CMOS image sensors that utilize correlated double sampling may use three (3T) or four transistors (4T) in the pixel, one of which serves as the charge transferring (TX) transistor. It is possible to share some of the pixel circuit transistors among several photodiodes, which also reduces the pixel size.

Image sensor 14 may be formed with one or more substrate layers. The substrate layers may be layers of semiconductor material such as silicon. The substrate layers may be connected using metal interconnects. An example is shown in FIG. 2 in which substrates 42, 44, and 46 are used to form image sensor 14. Substrates 42, 44 and 46 may sometimes be referred to as chips. Upper chip 42 may contain pinned photodiodes in pixel array 32. Floating diffusion regions and storage gates may also be included in upper chip 42 and/or middle chip 44. To ensure that there is adequate room for the photodiodes in upper chip 42, much of the pixel circuitry for the pixels may be formed in middle chip 44 and lower chip 46. Middle chip 44 may include an amplifier, reset transistor, and/or a source follower, for example.

Middle chip 44 may be bonded to upper chip 42 with an interconnect layer at every pixel or an interconnect for a group of pixels (e.g., two pixels, three pixels, more than three pixels, etc.). Bonding each pixel in upper chip 42 to corresponding pixel circuitry 34 in middle chip 44 (e.g., floating diffusion to floating diffusion) may be referred to as hybrid bonding. Middle chip 44 and lower chip 46 may not be coupled with hybrid bonding. Only peripheral electrical contact pads 36 of each chip may be bonded together (e.g., chip-to-chip connections 38). Each chip in image sensor 14 may include relevant circuitry. The upper chip may contain pinned photodiodes, floating diffusion regions, and storage gates. The middle chip may include a source follower transistor, one or more capacitors, and additional transistors. The bottom chip may include one or more of clock generating circuits, pixel addressing circuits, signal processing circuits such as the CDS circuits, analog to digital converter circuits, digital image processing circuits, and system interface circuits.

The example of FIG. 2 of image sensor 14 having three substrates is merely illustrative. If desired, the image sensor may be formed using a single substrate, using two substrates, or using more than three substrates. Each pair of adjacent substrates may optionally be bonded using hybrid bonding (e.g., a per-pixel metal interconnect layer) or may be bonded only at the periphery of the substrates.

In the example of FIG. 2, floating diffusion regions (sometimes referred to as floating diffusions) may be formed in middle substrate 44 instead of upper substrate 42 to allow more room for photodiodes in upper substrate 42. However, placing the floating diffusions (FDs) on the second chip may result in difficulties with kTC-reset noise elimination. When a photodiode, transfer gate, and floating diffusion region are all formed together in a single substrate, the transfer gates may transfer charge from the photodiode to the floating diffusion efficiently, completely, and nondestructively. In these cases, a correlated double sampling (CDS) charge readout scheme may be effectively implemented. However, when the floating diffusion region is formed in a different chip than the photodiode (as in FIG. 2), the transfer gates may not transfer charge from the photodiode to the floating diffusion efficiently, completely, and nondestructively and the correlated double sampling (CDS) charge readout scheme may therefore not be effective.

Transferring charge between the chips nondestructively and without loss of complete charge transfer may be difficult to accomplish. Therefore, in the image sensor described herein charge may be transferred using FD nodes that are conductively connected together between the chips. kTC-reset noise may be generated when the signal is read out using this scheme. However, herein the charge may be read out while eliminating kTC-reset noise.

FIG. 3 is a simplified cross-sectional side view of image sensor 14 showing imaging pixels along the column direction of the pixels. Pixels 301 are formed on a substrate 201 and are separated by deep trench isolation (DTI) 203. For the purpose of minimizing the dark current generation at the oxide-silicon interface, the DTIs are filled with hafnium oxide (HfO₂). The same oxide 202 (e.g., the same material that is used to fill the trenches in DTI 203) is also deposited on the back surface of the substrate 201. This example is merely illustrative and different materials may be used for the oxide in DTI 203 and oxide layer 202. The pixels are illuminated from the back side of the substrate as is indicated by photons 211. Each pixel may include a microlens 219 and color filter 220 deposited on the oxide 202. The pixels may further include pinned diodes formed by the p-type doped layer 206, n-type doped layer 208, and another p+ type doped layer 209. Adjacent to the pinned diode regions are polysilicon gates 205 (sometimes referred to as storage gates).

Floating diffusion 207 (which may be formed from a doped semiconductor region such as an n-type doped semiconductor layer) may be formed within p-type doped layer 206. The presence of p-type doping layer 206 between floating diffusion 207 and n-type doping layer 208 forms a potential barrier that does not allow accumulated electrons from the regions 208 to freely flow to the FD node. It is thus necessary to apply a punch through pulse to the FD node to accomplish the charge transfer from the pinned diode n-region (208) to the FD. The punch through pulse induces a bias that causes charge transfer from the pinned diode n-region (208) to the FD. The charge transfer is thus accomplished in a vertical direction. Charge transfer transistors at the surface of substrate 201 for transferring charge laterally to the floating diffusions are not included in the image sensor. The floating diffusions are connected together by via 212 to a common FD bus 214 (sometimes referred to as a signal line, FD signal line, etc.) that is further connected by via 216 to a hybrid bond pad 217. Polysilicon gates 205 are isolated from the substrate by an oxide layer 204 and the metal layers are isolated from the substrate and from each other by the oxide layers 213 and 215. Another oxide layer 218 may be deposited next to the bond pad 217. The various oxide layers (e.g., 204, 213, 215, and 218) may be formed from any desired type of oxide (e.g., silicon dioxide). Some or all of the oxide layers may be formed from the same material or the oxide layers may be formed from different materials.

As the photons 211 impinge on the pixels they generate electron-hole pairs 210. Electrons move to the pinned diode n-type regions 208 while holes move to the regions 209 that are biased at a ground potential. In order to read the accumulated electron charge from the pixels, it is necessary to apply a punch through pulse to the FDs. However, as indicated in the drawing, all of the FDs are connected together by the bus 214 and this would sum all charge in the pixels in one column together and deliver it to the readout circuit. This is not desirable. For this reason, only one of the polysilicon gates 205 in a column is biased low and the rest are biased high. This forces charge in all the pixels that have gates biased high to flow under the storage gates 205 from the n− regions 208 and only the one pixel with its storage gate biased low has charge stored in its n-region 208. The punch through pulse applied to the all FDs thus transfers charge only from one pixel to the readout circuits. This process is repeated and the gate biases are changed appropriately so that all the pixels can be scanned and transferred sequentially in a given column. Storage gates 205 therefore selectively store charge in pixels when it is desired to prevent the charge in those pixels from being read. Storage gate 205 is the only gate at the front surface of substrate 201 for each pixel. A transfer gate for transferring charge from the photodiode to the floating diffusion region is not present at the front surface of substrate 201 for the pixels.

In FIG. 3, because multiple pixels in a column share a single hybrid bond, the size of the hybrid bond pad does not limit the size of each imaging pixel. Charge may be transferred from pixels that have a smaller size than the hybrid bond pad to the readout circuits. In other words, each pixel may have a maximum lateral dimension (e.g., length or width, whichever is greater) that is smaller than the maximum lateral dimension of the hybrid bond pad.

FIG. 4 is a top view of illustrative pixel layout topology that illustrates one possibility of the placement of polysilicon gates, FD punch through metal bus lines, and the hybrid bond pads. Only two hybrid bond pads are shown for the simplicity of drawing. Also, for the same reason the pinned diode ground busses are omitted from the drawing.

Pixels are arranged in an array that may have essentially any arbitrary size. The pixels may be arranged in a grid of any desired number of rows and columns. In one illustrative example, the array may be an 8,000×8,000 grid of pixels (e.g., 8,000 rows and 8,000 columns). This example is merely illustrative. In general, the array of pixels may include more than 1,000 rows, more than 2,000 rows, more than 4,000 rows, more than 8,000 rows, less than 10,000 rows, between 5,000 and 10,000 rows, etc. The array of pixels may include more than 1,000 columns, more than 2,000 columns, more than 4,000 columns, more than 8,000 columns, less than 10,000 columns, between 5,000 and 10,000 columns, etc.

The polysilicon gates 205 may be driven from the array periphery. For example, row drivers in row control circuitry at the array periphery may provide a control signal (ϕₚ) to each polysilicon gate. In large arrays, the polysilicon gates 205 may have metal straps on top of them to reduce the driving pulse propagation delay time constant. The connections between the floating diffusion and the metal bus lines 214 (e.g., at vias 212 in FIG. 3) are indicated by the dots 304. The hybrid bond pads 217 (e.g., bond pad 217-1 and bond pad 217-2) have their size and separations determined by the fabrication processing layout design rules (e.g., manufacturing limitations). In this example, the hybrid bond pads may have lengths and widths of 1.0 micron. The hybrid bond pads may be separated by 1.0 micron. Connections between the hybrid bond pads 217 and the FD bus lines 214 (e.g., at via 216 in FIG. 3) are indicated by the dots 306. It is possible to adjust the layout for larger bond pads and larger spacing without changing the pixel size. It is important to notice that the hybrid bond pad 217-1 is offset from the hybrid bond pad 217-2 by the width of the pixel.

Multiple hybrid bond pads may be included in a single column of imaging pixels in the array or a single hybrid bond pad may be included for a single respective column of imaging pixels in the array. Each hybrid bond pad may channel signals from a given number (e.g., greater than one) of pixels in a respective column. The given number of pixels coupled to a given hybrid bond pad may be less than the total number of pixels in the column or may be equal to the total number of pixels in the column. In general, the hybrid bond pad may be coupled to any desired number of pixels (e.g., more than 10, 16, more than 20, more than 50, 64, more than 100, less than 100, more than 1000, less than 1000, between 4 and 100, between 2 and 1,000, etc.). For the pixel with size of 0.5 micron, the pixel circuits on the carrier chip have space of 2.0 um×2.0 um available for their circuits. Each pixel may have a length and width that are less than 0.5 micron, less than 1.0 micron, less than 0.8 micron, between 0.3 micron and 1.0 micron, etc. The hybrid bond pad may have a length and width that are greater than 1.0 micron, greater than 1.5 micron, greater than 2.0 micron, between 1.5 micron and 2.5 micron, less than 5.0 micron, etc.

FIG. 5 is a circuit diagram showing readout circuitry of an illustrative image sensor that is located on the carrier chip (e.g., middle chip 44 in FIG. 2). The readout circuitry may be arranged in readout circuitry blocks 417 that are associated with a respective hybrid bond pad. For simplicity, only two readout circuits are shown. Each readout circuitry block 417 may be overlapped by a corresponding hybrid bond pad 217 (and/or hybrid bond pad 401).

A first hybrid bond pad 401 (BP1) connects to the corresponding hybrid bond pad on the image sensing chip (e.g., 217 in FIG. 3), which allows the transfer of integrated photoelectron induced signal to the gate node of the inverting amplifier transistor 402 (e.g., an n-type transistor). The hybrid bond pad may sometimes be referred to as a metal interconnect layer. The metal interconnect layer may include a first bond pad on the image sensing chip, a second bond pad on the carrier chip, and corresponding vias electrically connected to the first and/or second bond pad.

The gain of the amplifier formed by transistor 402 is predominantly set by the value of the feedback capacitor 404 (Cf). The amplifier is reset by the reset transistor 403 and the punch through pulse signal is delivered to this node through the capacitor 409 (Cpt). The inverting amplifier transistor is biased by a current source represented by the p-channel transistor 408. The desired signal appears on the drain node of the inverting amplifier transistor 407 and is buffered by a source follower 405 with its source connected through the row addressing transistor 406 to the column sense line 419. The column sense line 419 also supplies the current bias to the source follower 405 from the current source 418 located at the periphery of the array. The signal that appears on the column sense line 419 is sensed and converted to a digital equivalent by an ADC located also at the periphery of the array. The appropriate control signals (V_{dd}, V_{d}, I_{b1}, ϕₚₜ₁, RS₁, AB₁, and Sx₁) are supplied to the circuit through the lines 411, 412, 413, 414, and 416 from the drivers located at the periphery of the pixel array. The line 410 supplies the V_{dd} drain bias to the circuit and the line 415 AB₁ supplies the ground bias to the circuit.

The circuit arrangement of FIG. 5 allows for correlated double sampling (CDS) signal processing to be used, which mitigates noise during sampling. The reference signal for the CDS operation is sensed just after the reset (e.g., which is performed by asserting reset transistor 403) and prior to application of the punch through pulse, while the photon charge induced signal is sensed after the punch through pulse has been applied. The reset signal may be subtracted from the photon charge induced signal to determine the amount of charge accumulated in the imaging pixel during the integration period.

The readout circuitry of FIG. 5 also provides antiblooming capability. When the pinned diode charge holding capacity is full, the additional charge overflows the FD punch through barrier (e.g., formed by p-type layer 206) and flows into the FD n+ region. When the amplifier is in a reset mode and the transistor 408 turned on, the overflow charge flows to the node 407 and eventually to the V_{d} drain bias line 411. However, the current source bias for the inverting amplifier transistor 402 cannot be kept on all the time during the charge integration period. This would increase the sensor power consumption beyond practical limits. On the other hand, the bias of the FD n+ node in the pixel needs to be kept approximately constant. This may present a problem when the reset transistor and the current source bias transistor 408 are turned off.

This problem is solved by turning the inverting amplifier transistor off by raising its ground bias potential (e.g., AB₁) up as it is supplied through the line 415 and dropping the V_{d} potential down to the approximate amplifier input node reset level as it is supplied through line 411. The reset transistor 408 may therefore be turned back on and the overflow charge from the FD may be drained to the lowered V_{d} bias supplied by the line 411. The current source transistor 408 serves now only as a switch and is fully turned on by applying an appropriate low bias to the line 412 from its current source level bias. The corresponding V_{d} bias signal, AB₁ bias signal, and the current source Ib bias signal are generated by the circuits located at the array periphery.

There are other options that may be used to keep the n+FD node biased at the reset level without having the constant current flowing through the inverting amplifier transistor. For example, another clamping transistor can be added to the circuit that would connect the FD node to a reset reference bias generated at the array periphery. However, the arrangement of FIG. 5 may use less space than an arrangement of this type.

In FIG. 5, BP1 may be coupled to a first respective hybrid bond pad 217. BP2 may be coupled to a second respective hybrid bond pad 217. The readout circuitry coupled to BP2 is identical to the readout circuitry coupled to BP1 (e.g., reach readout circuitry block 417 is the same).

FIG. 6 is a simplified timing diagram for the sensor showing the pulses applied in the readout interval 512. For simplicity, the diagram does not show pulses applied in the integration time interval 513 (where antiblooming is activated by raising AB₁ and lowering V_{d} as discussed above). Additionally, for simplicity, this timing diagram shows pulses applied only through the hybrid bond pads. Pulses applied to the polysilicon gates are the traces 505, 506, . . . , and 507 (e.g., ϕₚ₁, ϕₚ₂, . . . ϕₚₙ). The punch through pulses are the traces 508 and 510 (e.g., ϕₚₜ₁, ϕₚₜ₂). The reset pulses are the traces 509 and 511 (RS₁, RS₂). The sampling pulses for the CDS operation reference are indicated by the dashed vertical lines SR₁˜SRₙ and the sampling pulses for the signal are the dashed vertical lines SS₁˜SSₙ. The CDS reference voltage subtraction from the signal voltage (e.g., SR₁-SS₁, SR₂-SS₂, etc.) can be made either in the analog domain of in a digital domain by circuits located at the periphery of the array.

At the beginning of the readout period, I_{b1} may be low while I_{b2} is high and SX₁ is high while SX₂ is low. Readout of pixels associated with the first bond pad BP1 may be performed during this time period. The signal provided to each polysilicon gate may be temporarily lowered in sequence. While the polysilicon gate signal for the first row (e.g., ϕₚ₁) is low, the punch through signal for the first column (e.g., ϕₚₜ₁) is asserted. Then while the polysilicon gate signal for the second row (e.g., ϕₚ₂) is low, the punch through signal for the first column (e.g., ϕₚₜ₁) is asserted, etc. In this way, each pixel in a column may be sampled in sequence. Between each assertion of the punch through signal ϕₚₜ₁, reset signal RS₁ may be asserted to reset the FD bus line 214 associated with that column.

Before each assertion of the punch through signal and after the floating diffusion bus line is reset, a reset signal may be sampled (e.g., SR₁, SR₂, etc.). After each assertion of the punch through signal and before the floating diffusion bus line is reset again, a sample signal may be sampled (e.g., SS₁, SS₂, etc.). Once all of the pixels (e.g., n pixels) have been sampled, the process may repeat for the next bond pad.

Signal ϕₚₜ₂ may be low and signal RS₂ may be high during the sampling of pixels associated with the first bond pad. Similarly, during the sampling of pixels associated with the second bond pad, ϕₚₜ₁ may be low and RS₁ may be high. While the polysilicon gate signal for the first row (e.g., ϕₚ₁) is low, the punch through signal for the second column (e.g., ϕₚₜ₂) is asserted. Then while the polysilicon gate signal for the second row (e.g., ϕₚ₂) is low, the punch through signal for the second column (e.g., ϕₚₜ₂) is asserted, etc. In this way, each pixel in the second column may be sampled in sequence. Between each assertion of the punch through signal ϕₚₜ₂, reset signal RS₂ may be asserted to reset the FD bus line 214 associated with that column.

Therefore, an arrangement has been described where charge is transferred from a pinned photodiode (PD) to a floating diffusion (FD) in a vertical direction using the punch through concept which does not use a charge transfer gate. The pixel size is thus not compromised. The pixels may have submicron size, may have a large aperture efficiency, and may have a large quantum efficiency. The sensor arrays can have a large area. The size of the chip-to-chip bond pads does not limit the small pixel size.

The foregoing is merely illustrative of the principles of this invention and various modifications can be made by those skilled in the art without departing from the scope and spirit of the invention.

What is claimed is:

1. An image sensor comprising:
first and second semiconductor substrates;
an array of imaging pixels arranged in rows and columns, wherein each imaging pixel comprises:
a photodiode in the first semiconductor substrate;
a floating diffusion region in the first semiconductor substrate; and
a storage gate at a surface of the first semiconductor substrate;
a plurality of floating diffusion signal lines, wherein each floating diffusion signal line is coupled to a plurality of floating diffusion regions in a single column; and
a plurality of metal interconnect layers, wherein each metal interconnect layer electrically connects a respective floating diffusion signal line to a respective readout circuit in the second semiconductor substrate.

2. The image sensor defined in claim 1, wherein the first semiconductor substrate includes a plurality of isolation regions and wherein each isolation region is interposed between two respective photodiodes.

3. The image sensor defined in claim 2, wherein each one of the isolation regions is a deep trench isolation region that includes hafnium oxide, wherein the surface of the first semiconductor substrate is a front surface, and wherein an additional layer of hafnium oxide is formed at a back surface of the first semiconductor substrate.

4. The image sensor defined in claim 1, wherein no charge transferring transistors that laterally transfer charge between the photodiode and the floating diffusion region are included at the surface of the first semiconductor substrate.

5. The image sensor defined in claim 1, wherein charge is transferred from each photodiode to a respective floating diffusion region in a vertical direction using a charge punch through process.

6. The image sensor defined in claim 5, wherein the charge punch through process comprises applying a punch through signal to the respective floating diffusion region through a punch through capacitor in the second semiconductor substrate.

7. The image sensor defined in claim 1, wherein each metal interconnect layer comprises a hybrid bond that includes a first bond pad that is shorted to a respective floating diffusion signal line and a second bond pad that is shorted to a respective readout circuit in the second semiconductor substrate.

8. The image sensor defined in claim 1, wherein storage gates for all but one imaging pixel coupled to a given floating diffusion signal line are configured to store charge under the storage gates while the one remaining imaging pixel coupled to the given floating diffusion signal line is configured to store charge at the photodiode for a punch through charge transfer.

9. The image sensor defined in claim 1, wherein each readout circuit in the second semiconductor substrate comprises:
an inverting negative feedback amplifier transistor;
a feedback capacitor that sets an amplifier gain for the inverting negative feedback amplifier transistor;
a reset transistor; and
a current source biasing transistor.

10. The image sensor defined in claim 9, wherein each readout circuit in the second semiconductor substrate comprises:
a source follower transistor;
a column sense line; and
an addressing transistor that connects an output of the inverting negative feedback amplifier transistor through the source follower and the addressing transistor to the column sense line.

11. The image sensor defined in claim 10, wherein each readout circuit in the second semiconductor substrate comprises:
a p-channel transistor current source that biases the inverting negative feedback amplifier transistor drain, wherein the p-channel transistor is configured to bias the floating diffusion node to a reference potential through the reset transistor during a charge integration period causing overflow charge from the imaging pixel to be drained.

12. The image sensor defined in claim 11, wherein the inverting negative feedback amplifier transistor is configured to be turned off by biasing a source terminal of the inverting negative feedback amplifier transistor to a positive potential.

13. An image sensor comprising:
an image sensing chip comprising an array of imaging pixels that include photodiodes and floating diffusion regions;
a carrier chip including a plurality of readout circuits; and
a plurality of metal interconnect layers between the image sensing chip and the carrier chip, wherein each metal interconnect layer electrically connects a group of floating diffusion regions to a respective readout circuit of the plurality of readout circuits.

14. The image sensor defined in claim 13, wherein each imaging pixel includes a storage gate.

15. The image sensor defined in claim 13, wherein each metal interconnect layer is formed form a hybrid bond between a first bond pad on the image sensing chip and a second bond pad on the carrier chip, wherein each imaging pixel has a first maximum lateral dimension, and wherein each one of the first bond pads has a second maximum lateral dimension that is greater than the first maximum lateral dimension.

16. The image sensor defined in claim 13, wherein a length and a width of each imaging pixel are both less than 1 micron.

17. The image sensor defined in claim 13, wherein a punch through signal is configured to be applied to a respective floating diffusion region through the metal interconnect layer to transfer charge to that floating diffusion region.

18. An image sensor comprising:
an array of imaging pixels arranged in rows and columns, wherein each imaging pixel comprises:
a photodiode formed in a semiconductor substrate;
a floating diffusion region; and
a storage gate at a surface of the semiconductor substrate, wherein all but one storage gate in a given column of imaging pixels are configured to store charge under the respective storage gates away from respective photodiodes while the one storage gate in the given column transfers charge from a respective photodiode to a respective floating diffusion region.

19. The image sensor defined in claim 18, further comprising:
a plurality of signal lines, wherein each signal line is shorted to multiple floating diffusion regions in a respective column of imaging pixels.

20. The image sensor defined in claim 19, further comprising:
a plurality of hybrid bonds, wherein each hybrid bond is formed between a respective signal line and a readout circuit in an additional semiconductor substrate.
